(19) United States
(12) Patent Application Publication
(10) Pub. No.: US 2026/0150322 A1
(43) Pub. Date: May 28, 2026

(54) ALGAN COMPOUND SEMICONDUCTOR DEVICES

(71) Applicant: Analog Devices, Inc., Wilmington, MA (US)

(72) Inventors: James G. Fiorenza, Carlisle, MA (US); Daniel Piedra, Somerville, MA (US)

(21) Appl. No.: 19/094,112

(22) Filed: Mar. 28, 2025

Related U.S. Application Data
(60) Provisional application No. 63/725,354, filed on Nov. 26, 2024.
(60) Provisional application No. 63/737,577, filed on Dec. 20, 2024.

(51) Int. Cl. H10D 30/47; H10D 30/01; H10D 62/85; H10D 62/852

(52) U.S. Cl. CPC H10D 30/475; H10D 30/015; H10D 62/8503; H10D 62/852

(57) ABSTRACT

A compound semiconductor HEMT can be constructed as a graded bi-layer of AlGaN on AlGaN to create a 2DEG channel region in the underlying AlGaN region, and can employ techniques to create both depletion mode and enhancement mode HEMT structures. Injection transistor embodiments, electric field control embodiments, and bi-directional multi-gate embodiments are shown and described as well.

### CLAIM OF PRIORITY

This application claims priority to U.S. Provisional Application No. 63/737,577, filed Dec. 20, 2024, and U.S. Provisional Application No. 63/725,354, filed Nov. 26, 2024, which are hereby incorporated by reference herein in their entireties.

### TECHNICAL FIELD

This document pertains generally, but not by way of limitation, to semiconductor devices and processing, and more particularly but not by way of limitation to compound semiconductor devices with an AlGaN channel region.

### BACKGROUND

Compound semiconductor devices are useful in a number of applications, including as high-voltage, high power transistors, and in RF communications.

Gallium nitride (GaN) has been used in high electron mobility transistor (HEMT) devices, such as in which a “two-dimensional electron gas” (2DEG) channel region can be formed in the GaN near an interface with an interfacing material.

### SUMMARY/OVERVIEW

This application describes, among other things, examples of semiconductor processing that can be used to form a compound semiconductor device, such as an HEMT, in which a 2DEG channel region can be formed in an AlGaN material, such as in a body region of the HEMT.

A compound semiconductor HEMT can be constructed as a graded bi-layer of AlGaN on AlGaN to create a 2DEG channel region in the underlying AlGaN region, and can employ techniques to create both depletion mode and enhancement mode HEMT structures, which can be co-integrated on the same integrated circuit. Injection transistor embodiments, electric field control embodiments, and bi-directional multi-gate embodiments are shown and described as well.

For example, Example 1 can include or use a compound semiconductor integrated circuit. The compound semiconductor integrated circuit can include an aluminum gallium nitride (AlGaN) first layer that includes a transistor body region that includes a two-dimensional electron gas (2DEG) channel region of a first field-effect transistor. The first field-effect transistor further includes a gate terminal, a drain terminal, and a source terminal and defining a gate-drain access region and a gate-source access region. An AlGaN second layer can be formed overlying the AlGaN first layer, and having more aluminum content than the AlGaN first layer.

Example 2 can include or use one or more aspects of Example 1, and can further include a graded AlGaN third layer overlying the AlGaN second layer and underlying the gate terminal of the transistor. The transistor can be an enhancement mode transistor. The graded AlGaN third layer can decrease its aluminum content in a direction moving away from its interface with AlGaN second layer.

Example 3 can include or use one or more aspects of any of Examples 1-2, wherein an extension portion of the graded AlGaN third layer extends out from under the gate terminal of the transistor and over a drain-gate access region of the transistor.

Example 4 can include or use one or more aspects of any of Examples 1-3, wherein the extension portion of the graded AlGaN third layer decreases in thickness in a direction moving away from the gate terminal and toward the drain terminal of the transistor.

Example 5 can include or use one or more aspects of any of Examples 1-4, and can further include a separate graded AlGaN portion located over the gate-drain access region and electrically interconnected to the drain terminal of the transistor to provide a drain-embedded gate injection transistor.

Example 6 can include or use one or more aspects of any of Examples 1-5, and can further include a separate graded AlGaN portion located over the gate-drain access region, without being electrically interconnected to either of the gate terminal or the drain terminal of the transistor, such as to provide a superjunction transistor.

Example 7 can include or use one or more aspects of any of Examples 1-6, with the transistor including multiple independently addressable gate terminals, with corresponding underlying graded AlGaN regions, such as to provide a series connection between a first source/drain region of the transistor and a second source/drain region of the transistor.

Example 8 can include or use one or more aspects of any of Examples 1-7, with the transistor including a first separate graded AlGaN portion electrically connected to the first source/drain terminal of the transistor, and including a second separate graded AlGaN portion electrically connected to the second source/drain terminal of the transistor.

Example 9 can include or use one or more aspects of any of Examples 1-8, and further including an AlGaN fourth layer underlying the AlGaN first layer and having a greater aluminum content than the AlGaN first layer.

Example 10 can include a method of making a compound semiconductor integrated circuit, such as can include or use one or more aspects of any of Examples 1-9. The method can comprise forming an aluminum gallium nitride (AlGaN) first layer to provide a transistor body region that includes a two-dimensional electron gas (2DEG) channel region of a first field-effect transistor that further includes a gate terminal, a drain terminal, and a source terminal, and defining a gate-drain access region and a gate-source access region. The method can further include forming an AlGaN second layer, overlying the AlGaN first layer, and having more aluminum content than the AlGaN first layer.

Example 11 can include a method of making a compound semiconductor integrated circuit, such as can include or use one or more aspects of any of Examples 1-10. The method can include forming a graded AlGaN third layer overlying the AlGaN second layer and underlying the gate terminal of the transistor, wherein the transistor is an enhancement mode transistor, and wherein the graded AlGaN third layer decreases its aluminum content in a direction moving away from its interface with AlGaN second layer.

Example 12 can include a method of making a compound semiconductor integrated circuit, such as can include or use one or more aspects of any of Examples 1-11. The method can further include forming an extension portion of the graded AlGaN third layer that extends out from under the gate terminal of the transistor and over a drain-gate access region of the transistor.

Example 13 can include a method of making a compound semiconductor integrated circuit, such as can include or use one or more aspects of any of Examples 1-12. The method can include forming the extension portion of the graded AlGaN third layer to decrease in thickness in a direction moving away from the gate terminal and toward the drain terminal of the transistor.

Example 14 can include a method of making a compound semiconductor integrated circuit, such as can include or use one or more aspects of any of Examples 1-13. The method can include forming a separate graded AlGaN portion located over the gate-drain access region and electrically interconnected to the drain terminal of the transistor, such as to provide a drain-embedded gate injection transistor.

Example 15 can include a method of making a compound semiconductor integrated circuit, such as can include or use one or more aspects of any of Examples 1-14. The method can include forming a separate graded AlGaN portion located over the gate-drain access region, without being electrically interconnected to either of the gate terminal or the drain terminal of the transistor, such as to provide a superjunction transistor.

Example 16 can include a method of making a compound semiconductor integrated circuit, such as can include or use one or more aspects of any of Examples 1-15. The method can include forming multiple independently addressable gate terminals of the transistor, with corresponding underlying graded AlGaN regions, to provide a series connection between a first source/drain region of the transistor and a second source/drain region of the transistor.

Example 17 can include a method of making a compound semiconductor integrated circuit, such as can include or use one or more aspects of any of Examples 1-16. The method can include forming the transistor including a first separate graded AlGaN portion electrically connected to the first source/drain terminal of the transistor, and including a second separate graded AlGaN portion electrically connected to the second source/drain terminal of the transistor.

Example 18 can include a method of making a compound semiconductor integrated circuit, such as can include or use one or more aspects of any of Examples 1-17. The method can include forming, an on underlying substrate, an AlGaN fourth layer underlying the AlGaN first layer and having a greater aluminum content than the AlGaN first layer.

Example 19 can include a method of making a compound semiconductor integrated circuit, such as can include or use one or more aspects of any of Examples 1-18. The method can include forming the transistor as an enhancement mode transistor co-integrated on the same integrated circuit as a depletion mode transistor.

Example 20 can include a semiconductor integrated circuit, such as can include or use one or more aspects of any of Examples 1-19. The compound semiconductor integrated circuit can include an aluminum gallium nitride (AlGaN) first layer that includes a transistor body region that includes a two-dimensional electron gas (2DEG) channel region of a first field-effect transistor that further includes a gate terminal, a drain terminal, and a source terminal and defining a gate-drain access region and a gate-source access region. An AlGaN second layer can overlay the AlGaN first layer, and can have more aluminum content than the AlGaN first layer. A graded AlGaN third layer can overlay the AlGaN second layer and can underlay the gate terminal of the transistor, wherein the transistor is an enhancement mode transistor, and wherein the graded AlGaN third layer decreases its aluminum content in a direction moving away from its interface with AlGaN second layer, wherein an extension portion of the graded AlGaN third layer extends out from under the gate terminal of the transistor and over a drain-gate access region of the transistor, wherein the extension portion of the graded AlGaN third layer decreases in thickness in a direction moving away from the gate terminal and toward the drain terminal of the transistor. The transistor can include at least one of: (1) a separate graded AlGaN portion located over the gate-drain access region and electrically interconnected to the drain terminal of the transistor to provide a drain-embedded gate injection transistor; or (2) a separate graded AlGaN portion located over the gate-drain access region, without being electrically interconnected to either of the gate terminal or the drain terminal of the transistor, to provide a superjunction transistor.

Example 21 can include a compound semiconductor integrated circuit, such as can include or use one or more aspects of any of Examples 1-20, such as with the transistor including multiple independently addressable gate terminals, with corresponding underlying graded AlGaN regions, to provide a series connection between a first source/drain region of the transistor and a second source/drain region of the transistor. A first separate graded AlGaN portion can be electrically connected to the first source/drain terminal of the transistor, and including a second separate graded AlGaN portion electrically connected to the second source/drain terminal of the transistor. An AlGaN fourth layer can underlie the AlGaN first layer and can have a greater aluminum content than the AlGaN first layer.

This Summary/Overview is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1A shows an arrangement of semiconductor layers from which a depletion mode HEMT can be formed to provide a 2DEG channel region in AlGaN.

FIG. 1B shows a computer-simulated bandgap diagram corresponding to the structure of FIG. 1A, where the x-axis represents distance from the top surface moving from left-to-right on the x-axis.

FIG. 2A shows an example of a layering structure similar to that shown in FIG. 1A, but including an overlying fourth Alₓ₄GaN layer formed upon the third layer Alₓ₃GaN.

FIG. 2B shows an example of a computer-simulated bandgap diagram, corresponding to an enhancement mode arrangement shown in FIG. 2A.

FIG. 3 shows an example of an enhancement mode (EMODE) HEMT, such as can use the layering arrangement shown and described with respect to FIGS. 2A, 2B.

FIG. 4 shows an example of an enhancement mode HEMT, similar to that shown in FIG. 3, but with the graded Alₓ₄GaN layer formed to extend out from under the gate region and into the gate-drain access region of the HEMT device, such as with a varying thickness.

FIG. 5 shows an example of a drain-embedded injection transistor embodiment.

FIG. 6 shows an example of a superjunction FET enhancement mode embodiment.

FIGS. 7A, 7B, and 7C show an example of a multi-gate bidirectional enhancement mode HEMT device structure.

### DETAILED DESCRIPTION

One approach to constructing a compound semiconductor field-effect transistor (FET), such as a HEMT, can involve forming a bi-layer of aluminum nitride (AIN) upon gallium nitride (GaN) to form a “two-dimensional electron gas” (2DEG) channel region, which can be formed in the GaN near its interface with the overlying AlN material. The HEMT can be operated as a depletion mode (e.g., normally “on”) transistor. To form such an enhancement mode (e.g., normally “off”) transistor, an overlying layer of p-type GaN can be placed between the AlN and the gate region of the HEMT. The p-type GaN can be doped with magnesium, such as to donate electrical carriers referred to as “holes,” such as to shift the threshold voltage of the HEMT from depletion mode operation to enhancement mode operation. However, a high degree of magnesium doping may be needed to effect the desired threshold voltage shift from depletion mode to enhancement mode.

The present approach can include constructing a compound semiconductor integrated circuit HEMT as a graded bi-layer of AlGaN on AlGaN, such as to create a 2DEG channel region in the underlying AlGaN region forming a body region of the HEMT, and can include employing one or more techniques to allow creating both depletion mode and enhancement mode HEMT structures, which can be co-integrated on the same integrated circuit device.

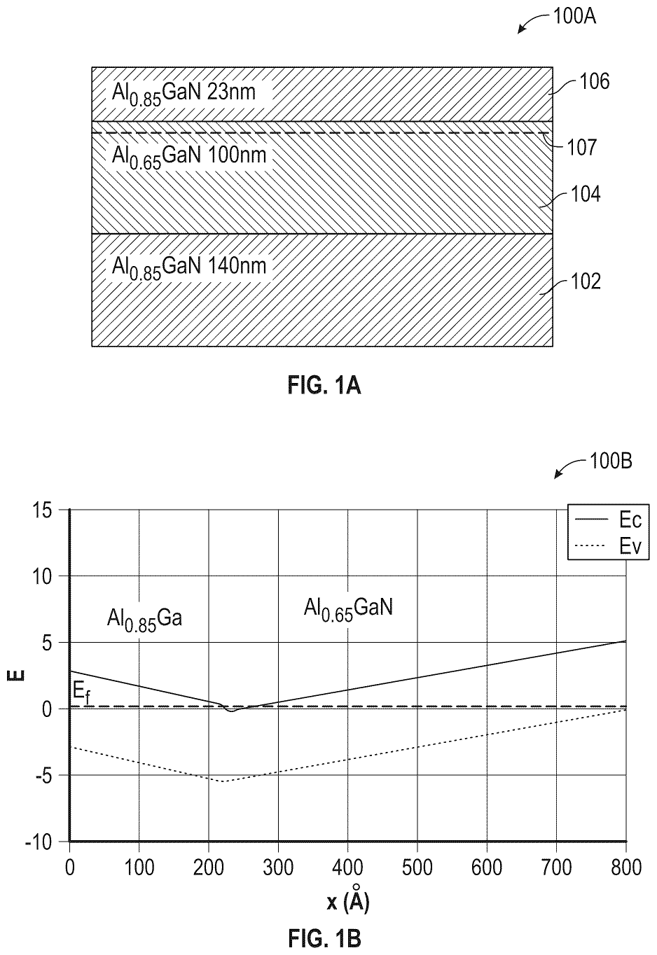

FIG. 1A shows an arrangement 100A of semiconductor layers from which a depletion mode HEMT can be formed to provide a 2DEG channel region in AlGaN. FIG. 1B shows a computer-simulated bandgap diagram 100B, corresponding to the structural arrangement 100A of FIG. 1A, in which the x-axis represents distance from the top surface of the arrangement 100A of FIG. 1A, moving from left-to-right on the x-axis in the bandgap diagram 100B of FIG. 1B.

FIG. 1A can be formed on a suitable underlying substrate, with the first Alₓ₁GaN layer 102 at a desired first thickness (e.g., 140 nanometers thickness), such as with x1=0.85. A second Alₓ₂GaN layer 104 can be formed on the first Alₓ₁GaN layer 102, such as with x2<x1 (e.g., x2=0.65) with the second Alₓ₂GaN layer 104 at a desired second thickness (e.g., 100 nanometers thickness). A third Alₓ₃GaN layer 106 can be formed on the second Alₓ₂GaN layer 104, such as with the third Alₓ₃GaN layer 106 having more (e.g., greater) aluminum content than the second Alₓ₂GaN layer 104, such as with x3>x2 (e.g., x3=0.85) and the third Alₓ₃GaN layer 106 at a desired third thickness (e.g., 23 nanometers thickness). A resulting 2DEG region 107 (shown in FIG. 1A by a dashed line) can be formed in the second Alₓ₂GaN layer 104. FIG. 1B shows an example of a computer-simulated bandgap diagram 100B, corresponding to the depletion mode layering arrangement 100A shown in FIG. 1A, with the Fermi level in 100B at least touching (e.g., at x=220 angstoms) the conduction band edge energy level Ec, which is shown together in 100B with its corresponding valence band edge energy level Ev, demonstrating an example of depletion mode operating capability of the layering structure 100A shown in FIG. 1A.

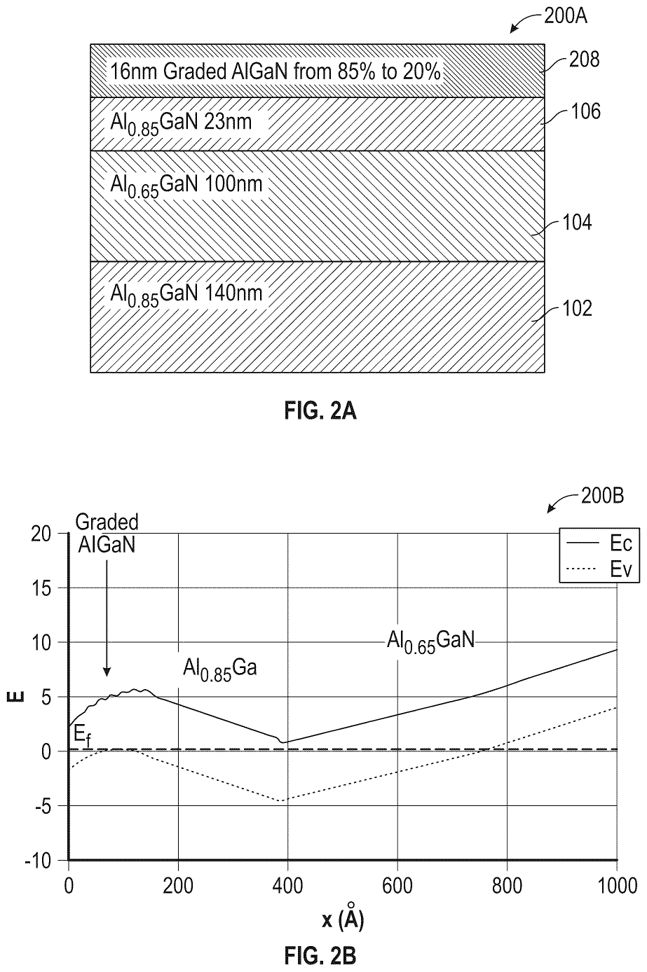

FIG. 2A shows an example of a layering structural arrangement 200A similar to that arrangement 100A shown in FIG. 1A, but including an overlying fourth Alₓ₄GaN layer 208 formed upon the third layer Alₓ₃GaN 106, such as with x4 being a graded layer that is graded from x4=0.85 at its interface with the third Alₓ₃GaN layer 106 to an x4=0.20 at or near its top surface of the arrangement 200A, such that the aluminum content of the graded layer decreases in a direction moving away from its interface with the third Alₓ₃GaN layer 106 FIG. 2B shows an example of a computer-simulated bandgap diagram 200B, corresponding to an enhancement mode arrangement 200A shown in FIG. 2A, with the Fermi level in 200B being less than the conduction band edge energy level Ec throughout the thickness, and showing the corresponding valence band energy level Ev. Thus, adding the graded Alₓ₄GaN layer 208 can enable enhancement mode operation when used in an HEMT device.

The thicknesses and proportions of the constituent materials (e.g., x1, x2, x3, and x4) described above with respect to FIGS. 1A, 1B, 2A, and 2B are illustrative of a specific example, but are not so limited. In some examples, the thickness of the layer 106 with 85% Al content is between about 15-30 nanometers (nm). In some examples, the thickness of the layer 104 is as thin as about 30 nm. In examples in which the layer 106 has 95% Al content, then the layer 106 can be as thin as about 10 nm and the layer 104 can be as thin as about 20 nm and still have a 2DEG.

An example of a process flow includes growing an Al_{0.85}GaN layer, then growing an Al_{0.65}GaN channel layer. Finally, the process includes growing a top barrier Al_{0.85}GaN layer. The Al content is one specific example.

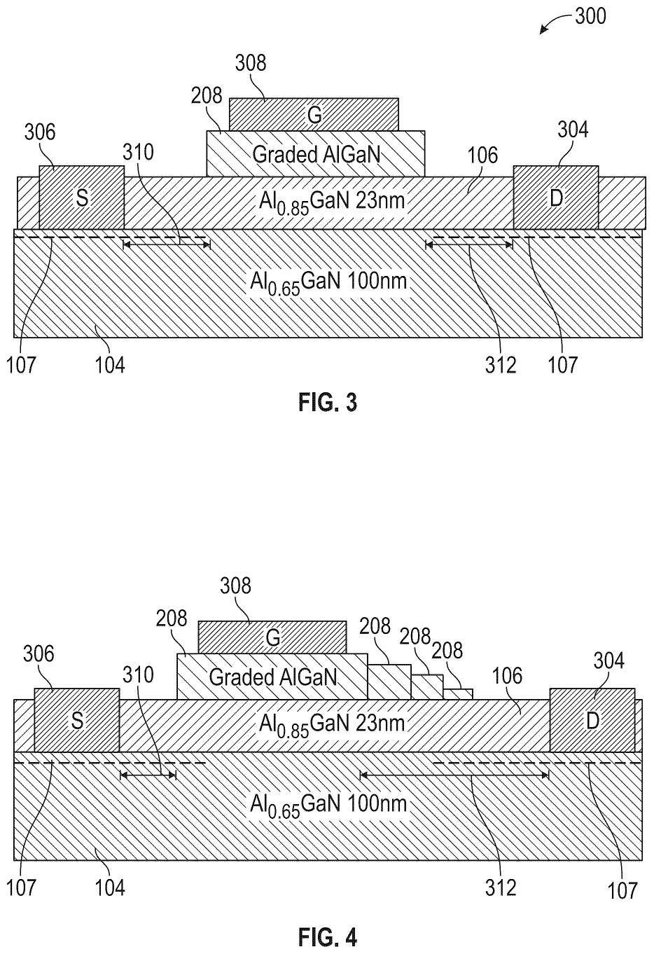

FIG. 3 shows an example of an enhancement mode (EMODE) HEMT structure 300, such as can use the layering arrangement 200A shown and described with respect to FIGS. 2A, 2B. FIG. 3 shows a drain region 304 and a source region 306 being formed in the third layer Alₓ₃GaN 106 and a gate region 308 being formed on the graded Alₓ₄GaN layer 208. The structure 300 shown in FIG. 3 defines a gate-source access region 310 between the gate terminal 308 and the source terminal 306 and a gate-drain access region 312 between the gate terminal 308 and the drain terminal 304. A 2DEG channel 107, represented by a dashed line, is present in each of these gate-drain access region 312 and gate-source access region 310 with the transistor operating in enhancement mode, such that applying an appropriate bias voltage to the gate terminal 308 to turn the transistor “on” results in the 2DEG channel 107 extending under the gate region 308 as well.

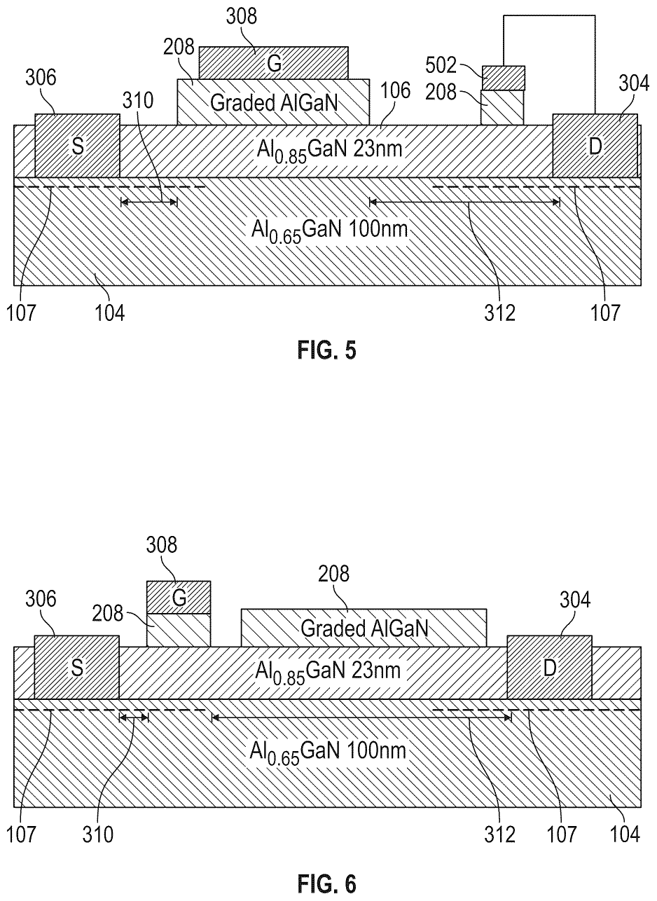

FIG. 4 shows an example of an enhancement mode HEMT, similar to that shown in FIG. 3, but with the graded Alₓ₄GaN layer 208 formed with an extension portion to extend out from under the gate region 308 and into the gate-drain access region 312 of the HEMT device, such as with a varying thickness that can decrease in a direction going from the gate region 308 and toward the drain region 304. This can allow p-type dopants from the graded Alₓ₄GaN layer 208 to be introduced into the drain-gate access region 312, such as partially turn-off the HEMT decreasingly in the drain-gate access region 312 in a direction going from the gate region 308 and toward the drain region 304 over which the graded Alₓ₄GaN layer 208 extends.

This can help provide electric field control, if desired, in the drain-gate access region 312, which is where the HEMT device would otherwise experience the highest electric field. Such electric field control can be particularly useful in high-voltage and/or high power applications, but may be useful in lower voltage and lower power (e.g., RF) applications as well.

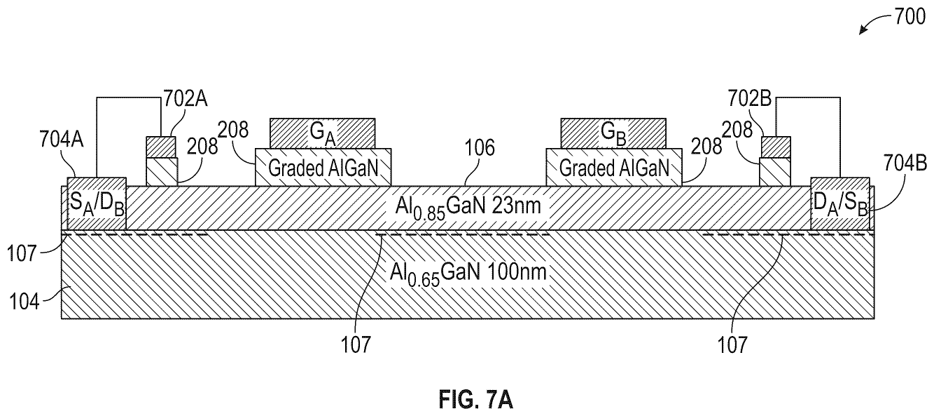

FIG. 5 shows an example of a drain-embedded injection transistor embodiment, which can provide an enhancement mode transistor similar to that shown in FIG. 3, but also including a separate portion of the Alₓ₄GaN layer 208 that can be overlaid with an appropriate material to form an injection terminal 502 that can be located over the drain-gate access region 312 and electrically connected to the drain terminal 304. The structure shown in FIG. 5 can help reduce the dynamic “on” resistance effects of the EMODE HEMT shown in FIG. 5, which can yield better efficiency in many applications, including in high-voltage and/or high-power switching applications. The structure shown in FIG. 5 can also help provide improved reliability, in that the injection terminal 502 that is electrically connected to the drain terminal 304 and can be used to inject holes that can help counteract trapping effects in the underlying structure.

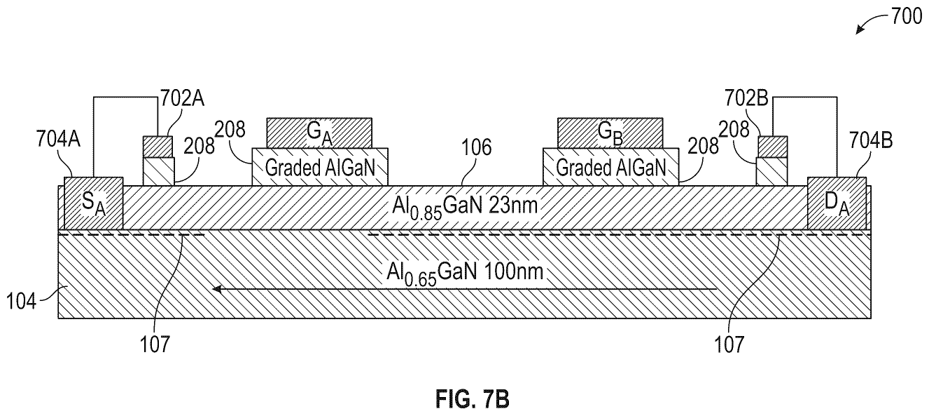

FIG. 6 shows an example of a superjunction FET enhancement mode embodiment, similar to what is shown in FIG. 3, but which can additionally include a separate portion of the Alₓ₄GaN layer 208 in the gate-drain access region 312 that need not be electrically interconnected to the drain terminal 304. The separate portion of the Alₓ₄GaN layer 208 in the gate-drain access region 312 can help provide balanced p-n matching to the 2DEG channel region 107, to provide superjunction FET operation. In FIG. 6, the graded Alₓ₄GaN layer 208 underlying the gate terminal 308 can be omitted if depletion mode operation is desired.

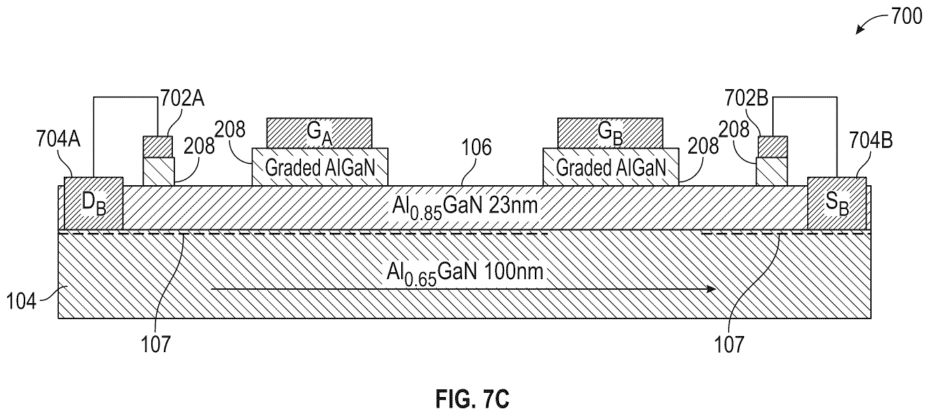

FIGS. 7A, 7B, and 7C show an example of a multi-gate bidirectional enhancement mode HEMT device structure 700. FIG. 7A shows an example of a structure 700 in which separate portions of the Alₓ₄GaN layer 208 can be included underlying multiple separate and independently addressable gates, GA and GB, and also included underlying injection terminals 702A-B that can be respectively electrically connected to corresponding adjacent source/drain terminals 704A-B, such as for operating similar to what was shown and described with respect to FIG. 5. The multiple independently addressable gate terminals can be selectively addressed to provide a series connection between first and second source/drain regions of the transistor.

FIG. 7B shows an example of the structure 700 of FIG. 7A being operated in a first “on” state (State A) in which the gate GA is acting as the gate, the left source/drain terminal 704A is acting as a source, and the right source/drain terminal 704B is acting as a drain, with electrical current flowing from right to left as shown by the arrow in FIG. 7B. FIG. 7C shows an example of the structure of FIG. 7A being operated in a second “on” state (State B) in which the gate GB is acting as the gate, the left source/drain terminal 704A is acting as a drain, and the right source/drain terminal 704B is acting as a source, with electrical current flowing from left to right as shown by the arrow in FIG. 7C. The corresponding 2DEG regions are shown by the dashed lines 107 in each of FIGS. 7A, 7B, and 7C.

The above description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects, and need not map directly to claim terminology, but instead such labels can be interchanged for mapping to claim terminology.

Geometric terms, such as “parallel”, “perpendicular”, “round”, or “square”, are not intended to require absolute mathematical precision, unless the context indicates otherwise. Instead, such geometric terms allow for variations due to manufacturing or equivalent functions. For example, if an element is described as “round” or “generally round,” a component that is not precisely circular (e.g., one that is slightly oblong or is a many-sided polygon) is still encompassed by this description.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods.

The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

The claimed invention is:

1. A compound semiconductor integrated circuit comprising:
an aluminum gallium nitride (AlGaN) first layer that includes a transistor body region that includes a two-dimensional electron gas (2DEG) channel region of a first field-effect transistor that further includes a gate terminal, a drain terminal, and a source terminal and defining a gate-drain access region and a gate-source access region; and
an AlGaN second layer, overlying the AlGaN first layer, and having more aluminum content than the AlGaN first layer.

2. The integrated circuit of claim 1, further including a graded AlGaN third layer overlying the AlGaN second layer and underlying the gate terminal of the transistor, wherein the transistor is an enhancement mode transistor, and wherein the graded AlGaN third layer decreases its aluminum content in a direction moving away from its interface with AlGaN second layer.

3. The integrated circuit of claim 2, wherein an extension portion of the graded AlGaN third layer extends out from under the gate terminal of the transistor and over a drain-gate access region of the transistor.

4. The integrated circuit of claim 3, wherein the extension portion of the graded AlGaN third layer decreases in thickness in a direction moving away from the gate terminal and toward the drain terminal of the transistor.

5. The integrated circuit of claim 1, further including a separate graded AlGaN portion located over the gate-drain access region and electrically interconnected to the drain terminal of the transistor to provide a drain-embedded gate injection transistor.

6. The integrated circuit of claim 1, further including a separate graded AlGaN portion located over the gate-drain access region, without being electrically interconnected to either of the gate terminal or the drain terminal of the transistor, to provide a superjunction transistor.

7. The integrated circuit of claim 1, with the transistor including multiple independently addressable gate terminals, with corresponding underlying graded AlGaN regions, to provide a series connection between a first source/drain region of the transistor and a second source/drain region of the transistor.

8. The integrated circuit of claim 7, with the transistor including a first separate graded AlGaN portion electrically connected to the first source/drain terminal of the transistor, and including a second separate graded AlGaN portion electrically connected to the second source/drain terminal of the transistor.

9. The integrated circuit of claim 1, further including an AlGaN fourth layer underlying the AlGaN first layer and having a greater aluminum content than the AlGaN first layer.

10. A method of making a compound semiconductor integrated circuit, the method comprising:
forming an aluminum gallium nitride (AlGaN) first layer to provide a transistor body region that includes a two-dimensional electron gas (2DEG) channel region of a first field-effect transistor that further includes a gate terminal, a drain terminal, and a source terminal, and defining a gate-drain access region and a gate-source access region; and
forming an AlGaN second layer, overlying the AlGaN first layer, and having more aluminum content than the AlGaN first layer.

11. The method of claim 10, comprising:
forming a graded AlGaN third layer overlying the AlGaN second layer and underlying the gate terminal of the transistor, wherein the transistor is an enhancement mode transistor, and wherein the graded AlGaN third layer decreases its aluminum content in a direction moving away from its interface with AlGaN second layer.

12. The method of claim 11, comprising:
forming an extension portion of the graded AlGaN third layer that extends out from under the gate terminal of the transistor and over a drain-gate access region of the transistor.

13. The method of claim 12, comprising:
forming the extension portion of the graded AlGaN third layer to decrease in thickness in a direction moving away from the gate terminal and toward the drain terminal of the transistor.

14. The method of claim 10, comprising:
forming a separate graded AlGaN portion located over the gate-drain access region and electrically interconnected to the drain terminal of the transistor to provide a drain-embedded gate injection transistor.

15. The method of claim 10, comprising:
forming a separate graded AlGaN portion located over the gate-drain access region, without being electrically interconnected to either of the gate terminal or the drain terminal of the transistor, to provide a superjunction transistor.

16. The method of claim 10, comprising:
forming multiple independently addressable gate terminals of the transistor, with corresponding underlying graded AlGaN regions, to provide a series connection between a first source/drain region of the transistor and a second source/drain region of the transistor.

17. The method of claim 16, comprising:
forming the transistor including a first separate graded AlGaN portion electrically connected to the first source/drain terminal of the transistor, and including a second separate graded AlGaN portion electrically connected to the second source/drain terminal of the transistor.

18. The method of claim 10, comprising:
forming, on an underlying substrate, an AlGaN fourth layer underlying the AlGaN first layer and having a greater aluminum content than the AlGaN first layer.

19. The method of claim 10, comprising:
forming the transistor as an enhancement mode transistor co-integrated on the same integrated circuit as a depletion mode transistor.

20. A compound semiconductor integrated circuit comprising:
an aluminum gallium nitride (AlGaN) first layer that includes a transistor body region that includes a two-dimensional electron gas (2DEG) channel region of a first field-effect transistor that further includes a gate terminal, a drain terminal, and a source terminal and defining a gate-drain access region and a gate-source access region;
an AlGaN second layer, overlying the AlGaN first layer, and having more aluminum content than the AlGaN first layer;
a graded AlGaN third layer overlying the AlGaN second layer and underlying the gate terminal of the transistor, wherein the transistor is an enhancement mode transistor, and wherein the graded AlGaN third layer decreases its aluminum content in a direction moving away from its interface with AlGaN second layer, wherein an extension portion of the graded AlGaN third layer extends out from under the gate terminal of the transistor and over a drain-gate access region of the transistor, wherein the extension portion of the graded AlGaN third layer decreases in thickness in a direction moving away from the gate terminal and toward the drain terminal of the transistor; and
at least one of: (1) a separate graded AlGaN portion located over the gate-drain access region and electrically interconnected to the drain terminal of the transistor to provide a drain-embedded gate injection transistor; or (2) a separate graded AlGaN portion located over the gate-drain access region, without being electrically interconnected to either of the gate terminal or the drain terminal of the transistor, to provide a superjunction transistor.

21. The integrated circuit of claim 20, with the transistor including:
multiple independently addressable gate terminals, with corresponding underlying graded AlGaN regions, to provide a series connection between a first source/drain region of the transistor and a second source/drain region of the transistor;
a first separate graded AlGaN portion electrically connected to the first source/drain terminal of the transistor, and including a second separate graded AlGaN portion electrically connected to the second source/drain terminal of the transistor; and
an AlGaN fourth layer underlying the AlGaN first layer and having a greater aluminum content than the AlGaN first layer.
